(19) United States
(12) Patent Application Publication
(10) Pub. No.: US 2023/0178359 A1
(43) Pub. Date: Jun. 8, 2023

(54) WAFER MANUFACTURING METHOD AND GRINDING APPARATUS

(71) Applicant: DISCO CORPORATION, Tokyo (JP)

(72) Inventors: Nobuyuki FUKUSHI, Tokyo (JP); Hiroshi KUROKAWA, Tokyo (JP); Shinji YAMASHITA, Tokyo (JP)

(21) Appl. No.: 18/060,820

(22) Filed: Dec. 1, 2022

(30) Foreign Application Priority Data
Dec. 3, 2021 (JP) 2021-197091

(51) Int. Cl. H01L 21/02; B24B 7/22; B24B 49/12

(52) U.S. Cl. CPC H01L 21/02013; B24B 7/228; B24B 49/12; H01L 29/1608

(57) ABSTRACT

In both a case where a workpiece is a regular workpiece having a first residual peeling layer on one surface thereof and a case where the workpiece is an adjustment workpiece not having the first residual peeling layer, a wafer having a predetermined thickness is manufactured by grinding opposite surfaces of the workpiece. That is, in the present invention, because the opposite surfaces of the workpiece are ground, wafers can be manufactured from two kinds of workpieces irrespective of whether or not the first residual peeling layer is present on the one surface of the workpiece. Hence, even when two kinds of workpieces are housed in a mixed manner in a first cassette, wafers having the predetermined thickness can be manufactured easily from these workpieces.

### BACKGROUND OF THE INVENTION

### Field of the Invention

The present invention relates to a wafer manufacturing method and a grinding apparatus.

### Description of the Related Art

In a technology disclosed in Japanese Patent Laid-Open No. 2016-111143, a laser beam having a wavelength transmissible through silicon carbide (SiC) is applied to a cylindrical SiC ingot from the side of an upper surface thereof while the focused spot of the laser beam is positioned inside the ingot at a predetermined depth, and the focused spot is moved in parallel with the upper surface. A peeling layer including a modified layer and cracks extending from the modified layer is thus formed. A disk-shaped workpiece is peeled off from the ingot with the peeling layer as a starting point. A wafer is manufactured from the ingot by grinding this workpiece.

In the manufacturing of wafers by using this technology, after a plurality of workpieces have been obtained from the ingot, a new ingot is irradiated with the laser beam to obtain other workpieces. At this time, when the power of the laser beam applied to the new ingot is the same as the power of the laser beam applied to the previous ingot, the peeling layer may become thinner or thicker than the peeling layer formed in the previous ingot.

In a case where the peeling layer is thin, it is difficult to peel off the workpiece from the ingot because, for example, adjacent cracks are not coupled to each other as viewed from the upper surface of the ingot. In a case where the peeling layer is thick, on the other hand, the workpiece peeled off from the ingot becomes thin, or the number of workpieces that can be obtained from the ingot is reduced.

In order to solve such problems, the peeling layer is made to have a predetermined thickness set in advance, by adjusting the power of the laser beam. That is, the thickness of the peeling layer is measured each time the ingot is changed.

In measuring the thickness of the peeling layer, after the peeling layer is formed in the ingot and the workpiece is peeled off from the ingot with the peeling layer as a starting point, the peeling layer remaining on the peeling surface of the ingot is ground and removed, and the peeling layer remaining on the peeling surface of the workpiece is ground and removed. Then, the thickness of the ingot from which the peeling layer has been removed and the thickness of the workpiece from which the peeling layer has been removed are subtracted from the thickness of the ingot in which the peeling layer is yet to be formed. The thickness of the peeling layer is thus obtained. Then, the power of the laser beam is adjusted such that the thus obtained thickness of the peeling layer falls within an allowable range set in advance. That is, until the thickness of the peeling layer falls within the allowable range set in advance, the following steps are repeated: the formation of a peeling layer, the peeling of a workpiece from the ingot, the removal of the peeling layer from the ingot and the workpiece, the measurement of the thickness of the peeling layer, and the adjustment of the power of the laser beam.

After the adjustment of the power of the laser beam is thus completed, the formation of a peeling layer, the peeling of a workpiece from the ingot, and the removal of the peeling layer remaining on the upper surface of the ingot are repeated. The workpiece thus obtained is housed into a cassette in a state in which the peeling layer remains on the workpiece. Then, the cassette is placed on a cassette stage of a grinding apparatus including two grinding mechanisms. One grinding mechanism removes the peeling layer from the workpiece. Thereafter, the other grinding mechanism removes grinding traces on opposite surfaces of the workpiece and grinds the workpiece to have a uniform thickness.

### SUMMARY OF THE INVENTION

The workpiece which is obtained at a time of the adjustment of the power of the laser beam and from which the peeling layer has been removed and the workpiece which is obtained after the adjustment of the power of the laser beam is ended and on which the peeling layer remains have different thicknesses and also have different surface states. Therefore, in the past, these workpieces have separately been ground and formed into wafers. Consequently, it requires time to grind workpieces until all of the workpieces that can be obtained from the ingot are formed into wafers.

It is accordingly an object of the present invention to provide a wafer manufacturing method and a grinding apparatus that, even when a workpiece having a peeling layer and a workpiece without the peeling layer are housed in a cassette in a mixed manner, can grind these workpieces to manufacture wafers having a predetermined thickness.

In accordance with an aspect of the present invention, there is provided a method for manufacturing a wafer by forming a peeling layer in an ingot, peeling off a plate-shaped workpiece from the ingot with the peeling layer as a starting point, and grinding the workpiece with use of grinding stones. The peeling layer is formed by applying a laser beam having a wavelength transmissible through the ingot to the ingot from a side of one surface of the ingot while a focused spot of the laser beam is positioned inside the ingot at a predetermined depth and then moving the focused spot of the laser beam in parallel with the one surface of the ingot. The method includes a power adjusting step of forming an adjustment peeling layer in the ingot, peeling off an adjustment workpiece from the ingot with the adjustment peeling layer as a starting point, removing a first residual peeling layer that is a peeling layer remaining on the adjustment workpiece, and adjusting power of the laser beam to be applied to the ingot, a workpiece obtaining step of obtaining a workpiece having a first residual peeling layer on one surface of the workpiece by forming a peeling layer in the ingot through application of the laser beam adjusted in power to the ingot and peeling off the workpiece from the ingot with the peeling layer as a starting point, and a grinding step of grinding opposite surfaces of the adjustment workpiece from which the first residual peeling layer has been removed and opposite surfaces of the workpiece having the first residual peeling layer, to manufacture wafers having a predetermined thickness.

Preferably, the power adjusting step includes a first thickness measuring step of measuring a first thickness that is a thickness of the ingot in which the adjustment peeling layer is yet to be formed, a first peeling layer forming step of forming the adjustment peeling layer in the ingot, a first peeling step of peeling off the adjustment workpiece from the ingot with the adjustment peeling layer as a starting point, a first ingot grinding step of grinding and removing, by peeling layer grindstones, a second residual peeling layer that is a peeling layer remaining on the ingot, a second thickness measuring step of measuring a second thickness that is a thickness of the ingot from which the second residual peeling layer has been removed through the grinding, a workpiece grinding step of grinding and removing, by the peeling layer grindstones, the first residual peeling layer of the adjustment workpiece peeled off from the ingot, a third thickness measuring step of measuring a third thickness that is a thickness of the adjustment workpiece from which the first residual peeling layer has been removed through the grinding, an adjustment peeling layer thickness measuring step of measuring a thickness of the adjustment peeling layer by subtracting the second thickness and the third thickness from the first thickness, and an adjusting step of adjusting the power of the laser beam such that the thickness of the adjustment peeling layer measured in the adjustment peeling layer thickness measuring step corresponds to a thickness set in advance.

Preferably, the workpiece obtaining step includes a second peeling layer forming step of forming the peeling layer in the ingot through the application of the laser beam adjusted in power to the ingot, a second peeling step of peeling off the workpiece from the ingot with the peeling layer as a starting point to obtain the workpiece having the first residual peeling layer and the ingot having a second residual peeling layer remaining after the workpiece is peeled off, a second ingot grinding step of grinding and removing the second residual peeling layer of the ingot after the second peeling step, and a repeating step of repeating the second peeling layer forming step, the second peeling step, and the second ingot grinding step to obtain workpieces each having the first residual peeling layer.

Preferably, the workpiece obtaining step includes housing, in a cassette in a mixed manner, the workpieces that are obtained in the repeating step and that each have the first residual peeling layer and the adjustment workpiece that is obtained in the power adjusting step and from which the first residual peeling layer has been removed.

Preferably, the grinding step includes a holding step of holding, on a holding surface of a chuck table, another surface of the workpiece having the first residual peeling layer on the one surface thereof, a peeling layer grinding step of grinding and removing, by peeling layer grindstones, the first residual peeling layer of the workpiece held on the holding surface, and a finish grinding step of grinding and removing, by finish grindstones, grinding traces formed on the opposite surfaces of the workpiece ground by the peeling layer grindstones.

Preferably, the grinding step may include a peeling layer presence or absence determining step of determining whether the first residual peeling layer is present or absent on the one surface of the workpiece. When it is determined that the first residual peeling layer is present, the first residual peeling layer of the workpiece is ground and removed by peeling layer grindstones, and the opposite surfaces of the workpiece are then ground by finish grindstones. On the other hand, when it is determined that the first residual peeling layer is absent, the opposite surfaces of the workpiece are ground by the finish grindstones without performing the grinding by the peeling layer grindstones.

Preferably, the peeling layer presence or absence determining step includes a fourth thickness measuring step of measuring a thickness of the workpiece held on a holding surface of a chuck table, and a thickness determining step of determining that the first residual peeling layer is present on the workpiece, when the thickness of the workpiece measured in the fourth thickness measuring step is equal to or more than a thickness set in advance, and determining that the first residual peeling layer is absent on the workpiece, when the thickness of the workpiece is smaller than the thickness set in advance.

Preferably, the peeling layer presence or absence determining step includes an imaging step of capturing an image of the one surface of the workpiece, and an image determining step of determining that the first residual peeling layer is present on the workpiece, when a difference in brightness between pixels adjacent to each other in the captured image is equal to or more than a difference set in advance, and determining that the first residual peeling layer is absent on the workpiece, when the difference in brightness between the pixels is smaller than the difference set in advance.

Preferably, the grinding step includes a first determining step of determining that the wafer is not able to be manufactured, when the thickness of the workpiece measured in the fourth thickness measuring step is smaller than at least a value obtained by adding together a grinding amount by which grinding is performed by the finish grindstones, the grinding amount being set in advance, and the predetermined thickness of the wafer set in advance.

Preferably, the grinding step may include a peeling layer presence or absence determining step of determining whether the first residual peeling layer is present or absent on the one surface of the workpiece. When it is determined that the first residual peeling layer is present, the first residual peeling layer of the workpiece is ground and removed by peeling layer grindstones, and the opposite surfaces of the workpiece are then ground by finish grindstones. On the other hand, when it is determined that the first residual peeling layer is absent, an additional thickness measuring step of measuring a thickness of the workpiece, a thickness adjusting grinding step of, when the thickness measured in the additional thickness measuring step is larger than a reference value that is a value obtained by adding together a grinding amount by which grinding is performed by the finish grindstones and the predetermined thickness of the wafer set in advance, grinding the workpiece by the peeling layer grindstones to a thickness of the reference value while forming grinding traces intersecting grinding traces formed on the workpiece, and a finish grinding step of grinding the opposite surfaces of the workpiece by the finish grindstones after the thickness adjusting grinding step are performed.

In accordance with another aspect of the present invention, there is provided a grinding apparatus including a cassette stage where a cassette in which workpieces are housed is placed, a chuck table having a holding surface for holding a workpiece thereon, a peeling layer grinding mechanism configured to grind, by peeling layer grindstones, a first residual peeling layer of the workpiece held on the holding surface, a finish grinding mechanism configured to grind, by finish grindstones, the workpiece held on the holding surface, a transporting mechanism configured to transport the workpiece between the cassette stage and the chuck table, an inverting mechanism configured to invert an upper surface and a lower surface of the workpiece, a thickness measuring instrument configured to measure a thickness of the workpiece held on the holding surface, a peeling layer presence or absence detecting unit configured to detect whether the first residual peeling layer is present or absent on one surface of the workpiece, and a controller. The controller performs control such that, when the peeling layer presence or absence detecting unit determines that the first residual peeling layer is present, the first residual peeling layer of the workpiece is ground and removed by the peeling layer grindstones and opposite surfaces of the workpiece are then ground by the finish grindstones, and performs control such that, when the peeling layer presence or absence detecting unit determines that the first residual peeling layer is absent, the opposite surfaces of the workpiece are ground by the finish grindstones without performing the grinding by the peeling layer grindstones.

Preferably, the peeling layer presence or absence detecting unit includes a thickness determining unit configured to measure, by the thickness measuring instrument, the thickness of the workpiece held on the holding surface, determine that the first residual peeling layer is present on the workpiece, when the thickness of the workpiece is equal to or more than a thickness set in advance, and determine that the first residual peeling layer is absent on the workpiece, when the thickness of the workpiece does not reach the thickness set in advance.

Preferably, the peeling layer presence or absence detecting unit includes a camera configured to capture an image of the one surface of the workpiece, and an image determining unit configured to determine that the first residual peeling layer is present on the workpiece, when a difference in brightness between pixels adjacent to each other in the image captured by the camera is equal to or more than a difference set in advance, and determine that the first residual peeling layer is absent on the workpiece, when the difference in brightness between the pixels is smaller than the difference set in advance.

In the method for manufacturing a wafer according to the present invention, the opposite surfaces of the workpiece are ground. Therefore, similar wafers can be manufactured from two kinds of workpieces regardless of whether or not the first residual peeling layer is present on the one surface of the workpiece. Hence, even when the two kinds of workpieces are housed in a mixed manner, wafers having a predetermined thickness can be manufactured easily from these workpieces. It is thus possible to shorten an overall processing time as compared with a case where the two kinds of workpieces are ground separately.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating a configuration of a laser processing apparatus;

FIG. 2 is a perspective view illustrating a grinding unit;

FIG. 3 is a perspective view illustrating a cassette stage and a cassette;

FIG. 4 is a perspective view illustrating a first robot;

FIG. 5 is a perspective view illustrating a first peeling layer forming step and a second peeling layer forming step;

FIG. 6 is a sectional view illustrating peeling layers formed in an ingot;

FIG. 7 is a perspective view illustrating a first peeling step and a second peeling step;

FIG. 8 is a perspective view illustrating the first peeling step and the second peeling step;

FIG. 9 is a perspective view illustrating a workpiece obtained in the first peeling step and the second peeling step;

FIG. 10 is a perspective view illustrating the ingot obtained in the first peeling step and the second peeling step;

FIG. 11 is a perspective view illustrating a configuration of a grinding apparatus;

FIG. 12 is a diagram illustrating an example of a captured image of a first residual peeling layer; and

FIG. 13 is a flowchart illustrating an example of a grinding step.

### DETAILED DESCRIPTION OF THE PREFERRED EMBODIMENT

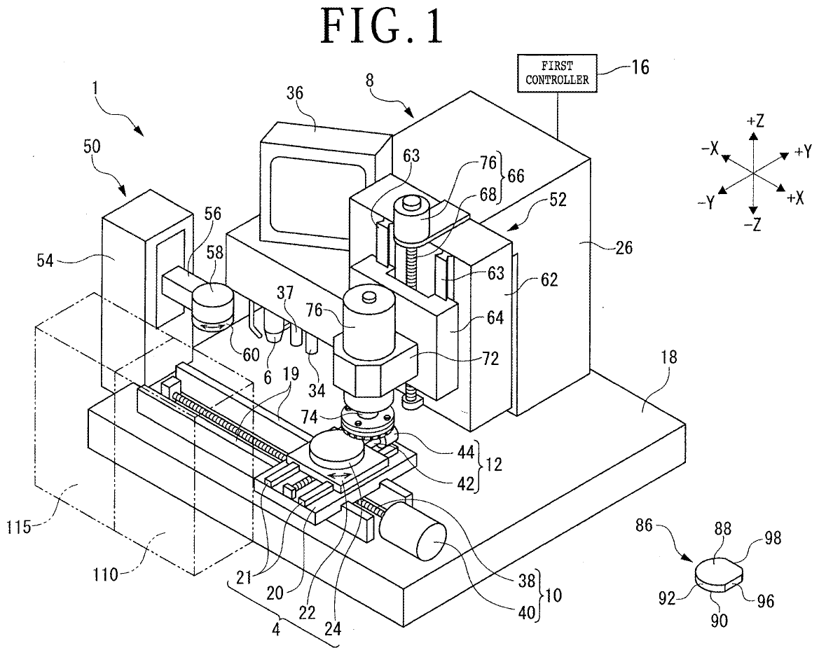

In a wafer manufacturing method according to an embodiment of the present invention, a wafer is manufactured by forming a peeling layer in an ingot 86 illustrated in FIG. 1, peeling off a plate-shaped workpiece to be described later from the ingot 86 with the peeling layer as a starting point, and grinding the workpiece with the use of grinding stones. In the formation of the peeling layer, a laser beam having a wavelength transmissible through the ingot 86 is applied to the ingot 86 from the side of a first end surface 88 of the ingot 86 while a focused spot of the laser beam is positioned inside the ingot 86 at a predetermined depth, and the focused spot is moved in parallel with the first end surface 88. A planar peeling layer parallel with the first end surface 88 is thus formed.

The wafer manufacturing method according to the present embodiment includes a power adjusting step, a workpiece obtaining step, and a grinding step. In the power adjusting step, the power of the laser beam to be applied to the ingot 86 is adjusted. In the workpiece obtaining step, a peeling layer is formed by irradiating the ingot 86 with the laser beam adjusted in power, and a workpiece is peeled off from the ingot 86 with the peeling layer as a starting point. In the grinding step, opposite surfaces of the workpiece are ground to manufacture a wafer having a predetermined thickness.

A laser processing apparatus 1 illustrated in FIG. 1 is an apparatus for performing the power adjusting step and the workpiece obtaining step described above. The laser processing apparatus 1 includes a holding unit 4 that holds the ingot 86 thereon, a laser beam irradiating unit 8 that has a condenser 6 and that forms a band-shaped peeling layer in the ingot 86 by the laser beam, an X-axis feeding unit 10 that processing-feeds the holding unit 4 and the condenser 6 relative to each other in an X-axis direction, a Y-axis feeding unit 12 that indexing-feeds the holding unit 4 and the condenser 6 relative to each other in a Y-axis direction, and a first controller 16.

For example, the laser processing apparatus 1 processes the ingot 86 in a cylindrical shape which is formed of SiC. The ingot 86 has the circular first end surface 88, a circular second end surface 90 that is opposite to the first end surface 88, and a peripheral surface 92. In addition, a first orientation flat 96 and a second orientation flat 98 in a rectangular shape that each indicate a crystal orientation are formed on the peripheral surface 92 of the ingot 86.

In addition, as illustrated in FIG. 6, the ingot 86 has a c-axis 511 (<0001> direction) and a c-plane 512 ({0001} plane) orthogonal to the c-axis 511. The c-axis 511 extends from the first end surface 88 to the second end surface 90 and is inclined by an off angle α with respect to a normal 513 to the first end surface 88. The off angle α can be set freely in a range of 1° to 6°, for example. The off angle α illustrated in FIG. 6 is 4°. The first orientation flat 96 is parallel with a direction in which the off angle α is formed. Further, the second orientation flat 98 is orthogonal to the direction in which the off angle α is formed.

The holding unit 4 illustrated in FIG. 1 is configured to hold such an ingot 86 as described above. The holding unit 4 includes an X-axis movable plate 20 mounted on a base 18 in such a manner as to be movable in the X-axis direction, guide rails 21 disposed on the X-axis movable plate 20, a Y-axis movable plate 22 mounted on the X-axis movable plate 20 in such a manner as to be movable in the Y-axis direction, a circular holding table 24 rotatably mounted on an upper surface of the Y-axis movable plate 22, and a holding table motor (not illustrated) that rotates the holding table 24.

The X-axis feeding unit 10 includes a ball screw 38 that extends in the X-axis direction along an upper surface of the base 18 and a motor 40 that rotates the ball screw 38. A nut portion (not illustrated) of the ball screw 38 is connected to the X-axis movable plate 20 of the holding unit 4. In the X-axis feeding unit 10, the ball screw 38 is rotated by the motor 40. The X-axis movable plate 20 is thus moved in the X-axis direction along guide rails 19 on the base 18.

The Y-axis feeding unit 12 includes a ball screw 42 that extends in the Y-axis direction along an upper surface of the X-axis movable plate 20 and a motor 44 that rotates the ball screw 42. A nut portion (not illustrated) of the ball screw 42 is connected to the Y-axis movable plate 22 of the holding unit 4. In the Y-axis feeding unit 12, the ball screw 42 is rotated by the motor 44. The Y-axis movable plate 22 is thus moved in the Y-axis direction along the guide rails 21 on the X-axis movable plate 20.

The laser beam irradiating unit 8 applies a laser beam to the ingot 86 held by the holding unit 4, to form a peeling layer in the ingot 86. The laser beam irradiating unit 8 includes a housing 26 disposed on the base 18 and the condenser 6 disposed on the housing 26.

The housing 26 includes a laser oscillator that emits a laser beam having a wavelength transmissible through the ingot 86, an attenuator that adjusts the power of the laser beam, a mirror that reflects the laser beam and guides the laser beam to the condenser 6, and the like (which are not illustrated).

The condenser 6 irradiates the ingot 86 with the laser beam while positioning the focused spot of the laser beam inside the ingot 86 at a depth corresponding to the thickness of a workpiece to be produced.

An imaging unit 34 that captures an image of the ingot 86 held by the holding unit 4 is fitted to a lower surface of a front end of the housing 26. In addition, a display unit 36 that displays the image captured by the imaging unit 34 is disposed on an upper surface of the housing 26.

In addition, a thickness measuring instrument 37 that measures the thickness of the ingot 86 or the workpiece held on the holding table 24 of the holding unit 4 is disposed in the vicinity of the imaging unit 34 on the housing 26.

The thickness measuring instrument 37 is, for example, a laser-type thickness measuring instrument that measures, in a noncontact manner, the thickness of the ingot 86 or the workpiece as a measurement target object. In this case, for example, the thickness measuring instrument 37 irradiates the measurement target object with a laser beam having a wavelength transmitted through the measurement target object, receives reflected light from a lower surface of the measurement target object and reflected light from an upper surface of the measurement target object, and measures the thickness of the measurement target object on the basis of an optical path difference between the reflected light from the lower surface and the reflected light from the upper surface. Alternatively, the thickness measuring instrument 37 may be a spectral-interference-type wafer thickness gauge that measures the thickness of the measurement target object by analyzing interference light between the reflected light from the lower surface of the measurement target object and the reflected light from the upper surface of the measurement target object. Incidentally, a wavelength range of a visible beam to infrared rays is preferably used for measurement light. The thickness measuring instrument 37 may include a super luminescent diode (SLD) as a light source that emits the measurement light.

Incidentally, the thickness measuring instrument 37 may calculate a height difference between a holding surface of the holding unit 4 and an upper surface of the workpiece by using a noncontact-type upper surface measuring instrument based on a white light confocal system, a noncontact-type upper surface height measuring instrument based on a triangulation system, or a contact-type upper surface height measuring instrument that senses the height position of a probe brought into contact with the upper surface of the workpiece, and may thus measure the thickness of the workpiece.

The laser processing apparatus 1 further includes a peeling unit 50 that peels off a wafer from the ingot 86 with the peeling layer as a starting point, and a grinding unit 52 that grinds the first end surface 88 of the ingot 86 to form the first end surface 88 into a flat surface.

The peeling unit 50 includes a casing 54 disposed at terminal end portions of the guide rails 19 on the base 18, an arm 56 that has a base end supported vertically movably by the casing 54 and that extends in the X-axis direction from the base end, and an arm raising and lowering unit (not illustrated) that raises and lowers the arm 56. The arm raising and lowering unit includes, for example, a ball screw that is connected to the arm 56 and that extends in an upward-downward direction and a motor that rotates the ball screw.

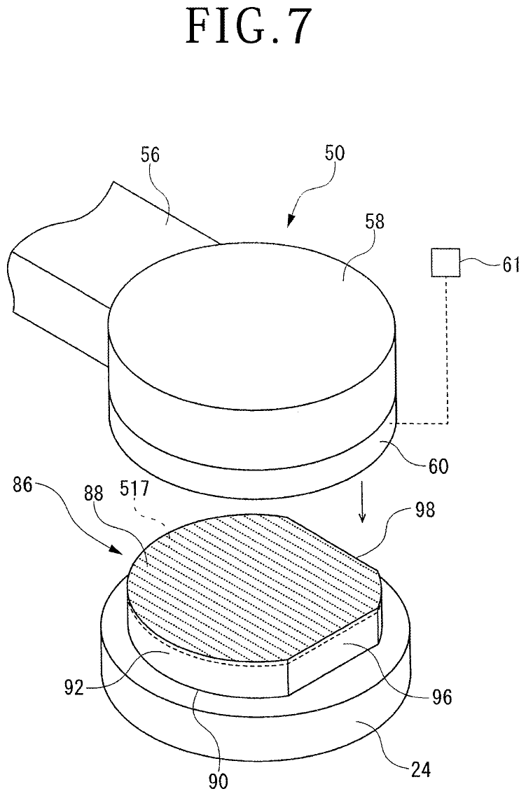

A motor 58 is attached to a distal end of the arm 56. A suction piece 60 is connected to a lower surface of the motor 58 in such a manner as to be rotatable about an axis extending in the upward-downward direction. A plurality of suction holes (not illustrated) are formed in a lower surface of the suction piece 60. The suction piece 60 is connected to a suction unit 61 (see FIG. 7). In addition, the suction piece 60 includes therein an ultrasonic vibration applying unit (not illustrated) that applies ultrasonic vibrations to the lower surface of the suction piece 60.

The grinding unit 52 includes a column 62, a raising and lowering plate 64 fitted vertically movably to one surface of the column 62, and a raising and lowering unit 66 that raises and lowers the raising and lowering plate 64. The raising and lowering unit 66 includes a ball screw 68 extending in the upward-downward direction along the one surface of the column 62 and a motor 70 that rotates the ball screw 68. A nut portion (not illustrated) of the ball screw 68 is connected to the raising and lowering plate 64. In the raising and lowering unit 66, the ball screw 68 is rotated by the motor 70. The raising and lowering plate 64 is thus raised or lowered along guide rails 63 attached to the one surface of the column 62.

A supporting wall 72 that projects in the Y-axis direction is fixed to one surface of the raising and lowering plate 64. A spindle 74 is supported by the supporting wall 72 in such a manner as to be rotatable about an axis extending in the upward-downward direction. A spindle motor 76 that rotates the spindle 74 is mounted on an upper surface of the supporting wall 72.

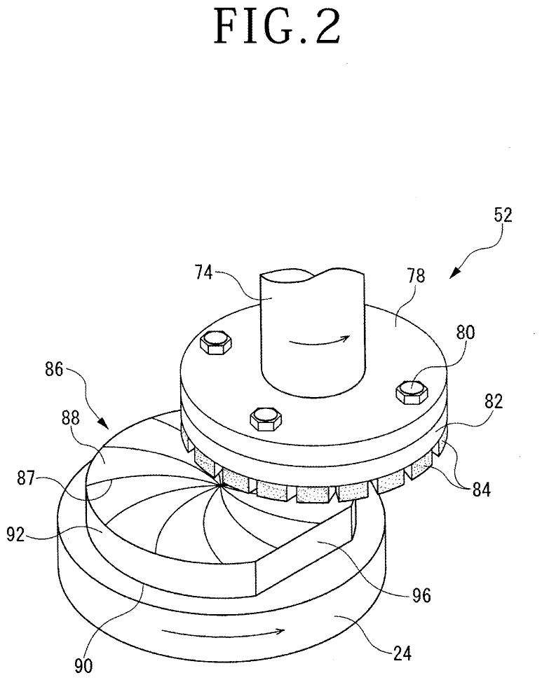

As illustrated in FIG. 1 and FIG. 2, a disk-shaped wheel mount 78 is fixed to a lower end of the spindle 74. An annular grinding wheel 82 is fixed to a lower surface of the wheel mount 78 by bolts 80. A plurality of peeling layer grindstones 84 which are arranged annularly at intervals in a circumferential direction are fixed to a peripheral edge portion of a lower surface of the grinding wheel 82. In the present embodiment, the peeling layer grindstones 84 are grindstones that remove a residual peeling layer remaining on the ingot 86 or the workpiece.

A cassette unit 110 and a first robot 115 are disposed on the front side (in −Y direction) of the base 18 of the laser processing apparatus 1.

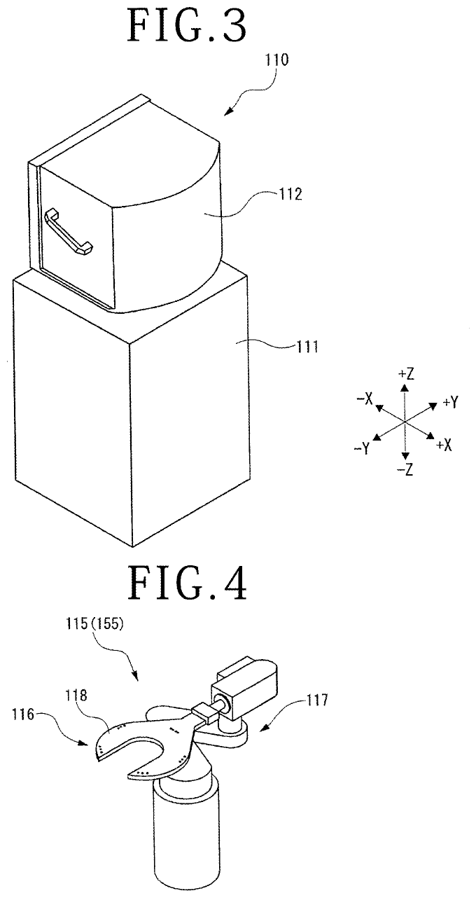

As illustrated in FIG. 3, the cassette unit 110 includes a cassette stage 111 and a first cassette 112 placed on the cassette stage 111. The first cassette 112 internally has a plurality of shelves. The first cassette 112 can house one workpiece on each shelf.

An opening (not illustrated) of the first cassette 112 is facing towards a −X direction. The first robot 115 is disposed on the side of this opening in the −X direction. As illustrated in FIG. 3, the first robot 115 includes a robot hand 116 that has a holding surface 118 for holding the workpiece thereon and a moving mechanism 117 that moves the robot hand 116. The first robot 115 is configured to house a workpiece obtained by the laser processing apparatus 1 into the first cassette 112 of the cassette unit 110.

The first controller 16 includes a central processing unit (CPU) that performs arithmetic processing according to a control program, a storage medium such as a memory, and the like. The first controller 16 controls each of the above-described members of the laser processing apparatus 1 to perform processing on the ingot 86.

Next, the power adjusting step and the workpiece obtaining step of the wafer manufacturing method according to the present embodiment which are performed by the laser processing apparatus 1 will be described.

[1. Power Adjusting Step]

The power adjusting step will first be described. In the power adjusting step, an adjustment peeling layer is formed in the ingot 86, and an adjustment workpiece is peeled off from the ingot 86 with the adjustment peeling layer as a starting point. Then, a first residual peeling layer as a peeling layer remaining on the adjustment workpiece and a second residual peeling layer as a peeling layer remaining on the ingot 86 are removed, and the power of the laser beam to be applied to the ingot 86 is adjusted. In the following, the power adjusting step will be described specifically.

(1-1. First Thickness Measuring Step)

First, an operator fixes the ingot 86 to an upper surface of the holding table 24 of the holding unit 4 by using an appropriate adhesive such that the first end surface 88 of the ingot 86 is oriented upward. The ingot 86 is thus held on the holding table 24. Incidentally, a plurality of suction holes may be formed in the upper surface of the holding table 24, and the ingot 86 may be held on the upper surface of the holding table 24 under suction.

Next, the first controller 16 controls the X-axis feeding unit 10 and the Y-axis feeding unit 12 to position the holding table 24 holding the ingot 86 thereon below the thickness measuring instrument 37. Then, the first controller 16 controls the thickness measuring instrument 37 to measure a first thickness which is the thickness of the ingot 86 held on the holding table 24. Incidentally, the thickness measuring instrument 37 that measures the thickness of the ingot 86 calculates, as the first thickness, a difference between the height of the upper surface of the holding table 24 and the height of the upper surface of the ingot 86 held on the holding table 24.

Incidentally, in the present embodiment, the first end surface 88 is planarized by the peeling layer grindstones 84 of the grinding unit 52 in advance. When the first end surface 88 is not planarized, the first controller 16 controls the peeling layer grindstones 84 of the grinding unit 52 to planarize the first end surface 88 before the thickness measuring instrument 37 measures the thickness of the ingot 86. This planarization of the first end surface 88 enables first peeling layer formation in a next step.

(1-2. First Peeling Layer Forming Step)

Next, the first controller 16 performs a first peeling layer forming step to form an adjustment peeling layer in the ingot 86.

In the first peeling layer forming step, the first controller 16 first controls the X-axis feeding unit 10 and the Y-axis feeding unit 12 to position the holding table 24 holding the ingot 86 thereon below the imaging unit 34. Then, the first controller 16 controls the imaging unit 34 to capture an image of the ingot 86 from above the ingot 86.

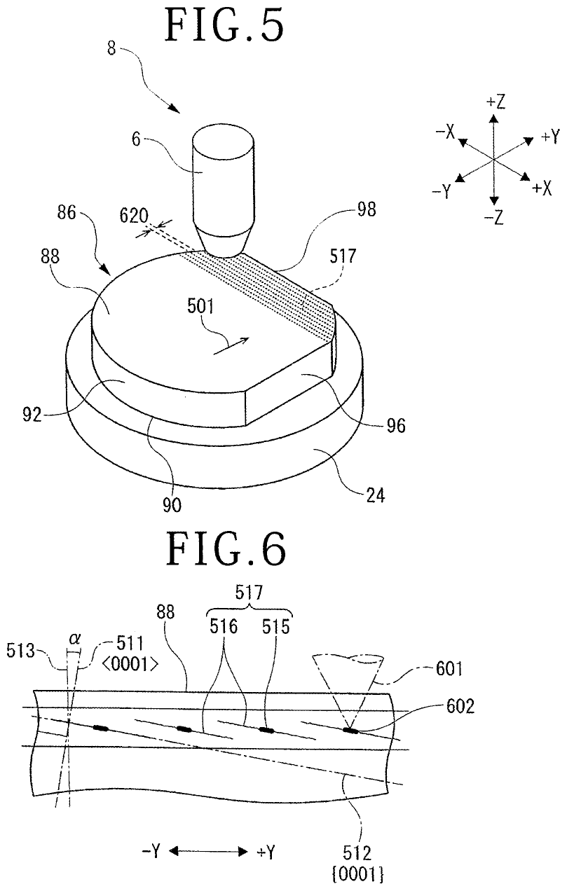

Next, on the basis of the image of the ingot 86 captured by the imaging unit 34, the first controller 16 controls the X-axis feeding unit 10, the Y-axis feeding unit 12, and the holding table motor to move and rotate the holding table 24, thereby adjusting the orientation of the ingot 86 to a predetermined orientation and also adjusting the positions of the ingot 86 and the condenser 6 in an XY plane. When the orientation of the ingot 86 is adjusted to the predetermined orientation, the second orientation flat 98 is aligned with the X-axis direction, as illustrated in FIG. 5. Consequently, a direction orthogonal to a direction 501 in which the off angle α (see FIG. 6) is formed is aligned with the X-axis direction, and the direction 501 in which the off angle α is formed is aligned with the Y-axis direction.

Next, the first controller 16 controls a focused spot position adjusting unit to raise or lower the condenser 6, thereby positioning a focused spot 602 (see FIG. 6) of a laser beam 601 inside the ingot 86 at a depth (first depth) corresponding to the thickness of the workpiece to be produced from the first end surface 88. Incidentally, the depth (first depth) from the first end surface 88 at which the focused spot 602 is positioned is preferably determined by using the value of the height of the upper surface of the ingot 86 which is measured by the thickness measuring instrument 37. Next, the first controller 16 controls the X-axis feeding unit 10 to processing-feed the holding table 24 in the X-axis direction at a predetermined processing feed speed, and at the same time, causes the condenser 6 to apply the laser beam 601 having a wavelength transmissible through the ingot 86 to the ingot 86.

Consequently, as illustrated in FIG. 5 and FIG. 6, a modified portion 515 is formed in the ingot 86 at the first depth from the first end surface 88. This modified portion 515 is formed as follows: when the laser beam 601 is applied to the ingot 86, SiC in the ingot 86 is separated into silicon (Si) and carbon (C), the laser beam 601 applied next is absorbed by C formed previously, and SiC is separated into Si and C in a chained manner.

Thus, the modified portion 515 is continuously formed in the X-axis direction orthogonal to the direction 501 in which the off angle α is formed. Further, cracks 516 isotropically extending along the c-plane from the modified portion 515 are generated. Consequently, a peeling layer 517 including the modified portion 515 and the cracks 516 is formed continuously along the X-axis direction.

Following this peeling layer formation processing, the first controller 16 controls the Y-axis feeding unit 12 to indexing-feed the ingot 86 and the focused spot 602 relative to each other in the Y-axis direction by a predetermined indexing feed amount 620 in a range not exceeding the width of the cracks 516.

Then, the first controller 16 alternately repeats the peeling layer formation processing and the indexing feed. Consequently, a plurality of peeling layers 517 continuously extending in the X-axis direction can be formed at intervals of the predetermined indexing feed amount 620 in the Y-axis direction.

In this way, the plurality of peeling layers 517 along the X-axis direction can sequentially be generated in the ingot 86 at the first depth from the first end surface 88. The peeling layers 517 are portions that are decreased in strength due to the modified portions 515 and the cracks 516 and that serve as an interface for peeling off a workpiece from the ingot 86. In the present embodiment, the peeling layers 517 generated in the first peeling layer forming step are used as an adjustment peeling layer.

(1-3. First Peeling Step)

Next, the first controller 16 performs a first peeling step to peel off an adjustment workpiece from the ingot 86 with the adjustment peeling layer as a starting point.

In the first peeling step, the first controller 16 first controls the X-axis feeding unit 10 and the Y-axis feeding unit 12 to position the holding table 24 holding the ingot 86 thereon below the suction piece 60 of the peeling unit 50 as illustrated in FIG. 7.

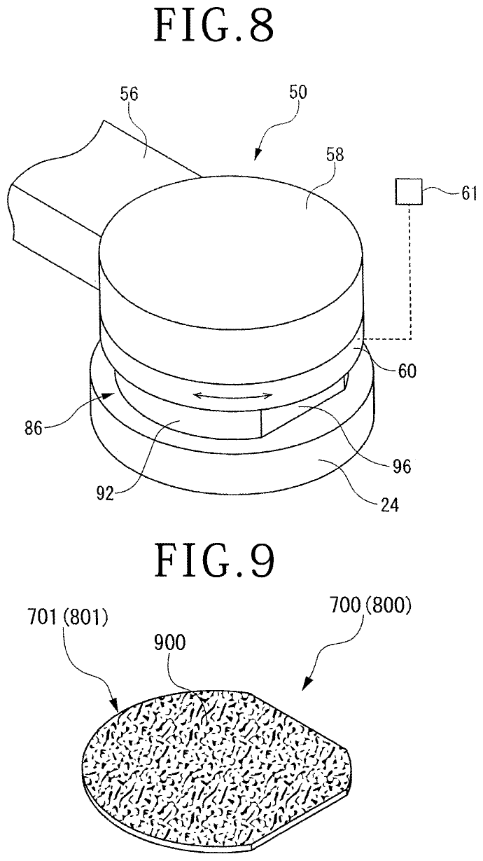

Next, the first controller 16 controls the arm raising and lowering unit to lower the arm 56, thereby bringing the lower surface of the suction piece 60 into close contact with the first end surface 88 of the ingot 86 as illustrated in FIG. 8. Then, the first controller 16 actuates the suction unit 61 to make the lower surface of the suction piece 60 suck the first end surface 88 of the ingot 86. Next, the first controller 16 actuates the ultrasonic vibration applying unit to apply ultrasonic vibrations to the lower surface of the suction piece 60, and also actuates the motor 58 to rotate the suction piece 60. Consequently, as illustrated in FIG. 9, an adjustment workpiece 700 can be peeled off from the ingot 86 with the adjustment peeling layer as a starting point.

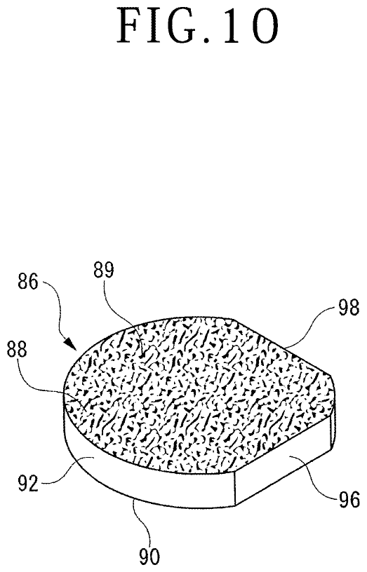

It is to be noted that, as illustrated in FIG. 9, a first residual peeling layer 900 as a part of the adjustment peeling layer remains on a peeling surface 701 that is one surface of the adjustment workpiece 700. In addition, as illustrated in FIG. 10, a second residual peeling layer 89 as a part of the adjustment peeling layer also remains on the first end surface 88 of the ingot 86 from which the adjustment workpiece 700 has been peeled off. Incidentally, the other surface of the adjustment workpiece 700 is a surface corresponding to the first end surface 88 of the ingot 86 that is yet to undergo the first peeling step, and is hence planarized.

(1-4. First Ingot Grinding Step)

Next, the first controller 16 performs a first ingot grinding step to grind and remove the second residual peeling layer 89 as the residual peeling layer of the ingot 86 by the peeling layer grindstones 84.

In the first ingot grinding step, the first controller 16 first controls the X-axis feeding unit 10 and the Y-axis feeding unit 12 (see FIG. 1) to position the holding table 24 below the grinding wheel 82 of the grinding unit 52 as illustrated in FIG. 2. Next, the first controller 16 actuates the holding table motor of the holding unit 4 to rotate the holding table 24 counterclockwise as viewed from above. In addition, the first controller 16 actuates the spindle motor 76 (see FIG. 1) of the grinding unit 52 to rotate the spindle 74 counterclockwise as viewed from above.

Next, the first controller 16 controls the raising and lowering unit 66 of the grinding unit 52 to lower the spindle 74, thereby bringing the peeling layer grindstones 84 into contact with the first end surface 88 of the ingot 86. Thereafter, the first controller 16 causes the spindle 74 to lower at a predetermined grinding feed speed, and the first end surface 88 of the ingot 86 is thus ground by the peeling layer grindstones 84. In this way, the second residual peeling layer 89 formed on the first end surface 88 of the ingot 86 can be ground and removed. Incidentally, grinding traces 87 are formed by the peeling layer grindstones 84 on the planarized first end surface 88 from which the second residual peeling layer 89 has been removed through this grinding.

(1-5. Second Thickness Measuring Step)

Next, the first controller 16 controls the thickness measuring instrument 37 to measure a second thickness that is the thickness of the ingot 86 from which the second residual peeling layer 89 has been removed through the grinding, as in the first thickness measuring step.

(1-6. Workpiece Grinding Step)

Next, the first controller 16 performs the workpiece grinding step to grind and remove, by the peeling layer grindstones 84, the first residual peeling layer 900 as the residual peeling layer of the adjustment workpiece 700 peeled off from the ingot 86.

Specifically, the operator first removes the ingot 86 from the holding table 24 of the holding unit 4, and makes the holding table 24 hold the adjustment workpiece 700 such that the peeling surface 701 on which the first residual peeling layer 900 is formed is oriented upward. Incidentally, a transporting mechanism that transports the adjustment workpiece 700 peeled off from the ingot 86 to the holding table 24 may be provided.

Thereafter, as in the first ingot grinding step described above, the first controller 16 causes the peeling layer grindstones 84 to grind the first residual peeling layer 900 of the adjustment workpiece 700 held on the holding table 24 of the holding unit 4 from the peeling surface 701. The first residual peeling layer 900 formed on the adjustment workpiece 700 can thus be ground and removed. Incidentally, as a result of this grinding, the adjustment workpiece 700 becomes a workpiece having opposite surfaces thereof planarized. In addition, grinding traces (not illustrated) are formed by the peeling layer grindstones 84 on the opposite surfaces of the adjustment workpiece 700.

(1-7. Third Thickness Measuring Step)

Next, the first controller 16 controls the thickness measuring instrument 37 to measure a third thickness that is the thickness of the adjustment workpiece 700 from which the first residual peeling layer 900 has been removed through the griding, as in the first thickness measuring step. After the third thickness measuring step, the first robot 115 illustrated in FIG. 4 houses the adjustment workpiece 700 into the first cassette 112 of the cassette unit 110 illustrated in FIG. 3.

(1-8. Adjustment Peeling Layer Thickness Measuring Step)

Next, the first controller 16 measures the thickness of the adjustment peeling layer formed in the ingot 86 in the first peeling layer forming step, by subtracting the second thickness, which is the thickness of the ingot 86 from which the adjustment workpiece 700 has been peeled off and from which the second residual peeling layer 89 has been removed, and the third thickness, which is the thickness of the adjustment workpiece 700 from which the first residual peeling layer 900 has been removed, from the first thickness, which is the thickness of the ingot 86 from which the adjustment workpiece 700 is yet to be peeled off.

(1-9. Power Adjusting Step)

Next, the first controller 16 controls the attenuator of the laser beam irradiating unit 8 or the like to adjust the power of the laser beam to be applied from the condenser 6 such that the thickness of the adjustment peeling layer measured in the adjustment peeling layer thickness measuring step corresponds to a thickness set in advance.

[2. Workpiece Obtaining Step]

The workpiece obtaining step will next be described. In the workpiece obtaining step, a peeling layer is formed by irradiating the ingot 86 with the laser beam adjusted in power in the power adjusting step, and a workpiece is peeled off from the ingot with the peeling layer as a starting point. Thus, the workpiece having a first residual peeling layer 900 is obtained.

(2-1. Second Peeling Layer Forming Step)

In the second peeling layer forming step, the operator makes the ingot 86 held on the holding table 24 of the holding unit 4 with the first end surface 88 oriented upward (see FIG. 5). Then, the first controller 16 causes the condenser 6 to apply the laser beam adjusted in power to the ingot 86 from the first end surface 88 side, thereby forming peeling layers 517 in the ingot 86. That is, as in the first peeling layer forming step described above, the first controller 16 causes the focused spot 602 (see FIG. 6) of the laser beam 601, which is adjusted in power, to be positioned inside the ingot 86 at a depth (first depth) corresponding to the thickness of the workpiece to be produced from the first end surface 88, to thereby form the peeling layers 517 at this position.

(2-2. Second Peeling Step)

Next, the first controller 16 performs a second peeling step to obtain the workpiece which has been peeled off from the ingot 86 with the peeling layers 517 as a starting point and which has the first residual peeling layer 900 and the ingot 86 from which the workpiece has been peeled off and which has the second residual peeling layer 89.

In the second peeling step, as in the first peeling step described above, the first controller 16 controls the peeling unit 50 to peel off the workpiece from the ingot 86 held on the holding table 24. In the following, the workpiece obtained in the second peeling step will be referred to as a regular workpiece 800 (see FIG. 9).

As in the case of the adjustment workpiece 700, as illustrated in FIG. 9, the first residual peeling layer 900 as a part of the peeling layer remains on a peeling surface 801 that is one surface of the regular workpiece 800. Incidentally, the other surface of the regular workpiece 800 is planarized in a second ingot grinding step to be described later.

In addition, as illustrated in FIG. 10, the second residual peeling layer 89 as a part of the peeling layer also remains on the first end surface 88 of the ingot 86 from which the regular workpiece 800 has been peeled off. The first controller 16 thus obtains the workpiece having the first residual peeling layer 900 on the one surface thereof and the ingot 86 having the second residual peeling layer 89 on the first end surface 88.

(2-3. Second Ingot Grinding Step)

After the second peeling step, the first controller 16 grinds and removes the second residual peeling layer 89 of the ingot 86. Specifically, as in the first ingot grinding step described above, the first controller 16 causes the peeling layer grindstones 84 to grind the first end surface 88 of the ingot 86 held on the holding table 24 of the holding unit 4 (see FIG. 2). Consequently, the second residual peeling layer 89 formed on the first end surface 88 of the ingot 86 is ground and removed, and the first end surface 88 can thus be planarized. Incidentally, grinding traces 87 are formed on the first end surface 88 of the ingot 86 by this grinding.

(2-4. Repeating Step)

Then, the first controller 16 repeatedly performs the second peeling layer forming step, the second peeling step, and the second ingot grinding step described above to obtain a plurality of regular workpieces 800 each having the first residual peeling layer 900 on one surface thereof.

Incidentally, the first robot 115 illustrated in FIG. 4 houses the regular workpieces 800 into the first cassette 112 of the cassette unit 110 illustrated in FIG. 3. That is, the workpiece obtaining step includes a step of housing, in the first cassette 112 in a mixed manner, the regular workpieces 800 which are obtained in the repeating step and which each have the first residual peeling layer 900, and the adjustment workpiece 700 which is obtained in the power adjusting step and from which the first residual peeling layer 900 has been removed.

In this way, the first cassette 112 can house the regular workpieces 800 having one surface formed with the first residual peeling layer 900 and having the other surface planarized and the adjustment workpiece 700 having opposite surfaces, i.e., one surface and the other surface, planarized and not having the first residual peeling layer 900. Incidentally, the first robot 115 houses the adjustment workpiece 700 and the regular workpieces 800 into the first cassette 112 such that the one surfaces of the adjustment workpiece 700 and the regular workpieces 800 are oriented upward. Hence, the regular workpieces 800 are each housed in the first cassette 112 such that the one surface on which the first residual peeling layer 900 is formed is oriented upward.

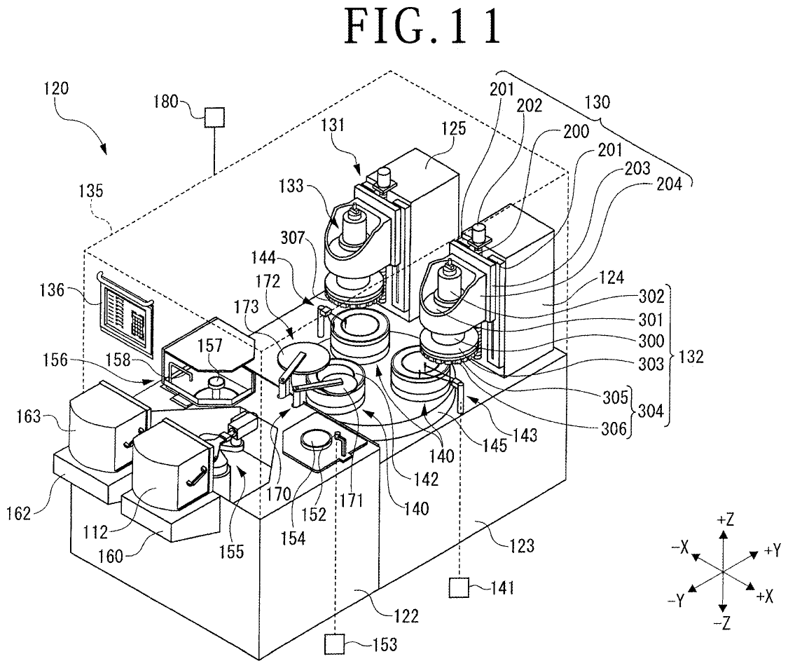

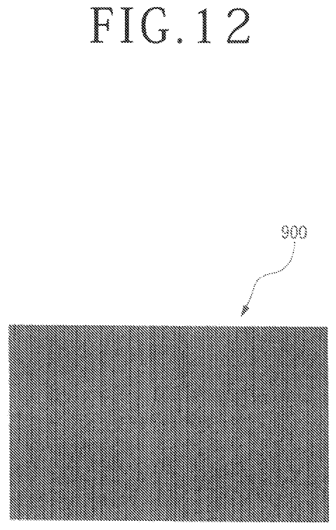

In the present embodiment, these regular workpieces 800 and the adjustment workpiece 700 are ground in the grinding step of the wafer manufacturing method according to the present embodiment, and are formed into wafers having a predetermined thickness. The grinding step is performed by a grinding apparatus 120 illustrated in FIG. 11.

A configuration of the grinding apparatus 120 will first be described. The grinding apparatus 120 includes a peeling layer grinding mechanism 132 and a finish grinding mechanism 133. The grinding apparatus 120 grinds a processing target workpiece held on a chuck table 140, by the peeling layer grinding mechanism 132 and the finish grinding mechanism 133. Incidentally, the “processing target workpiece” refers to a workpiece to be subjected to grinding processing by the grinding apparatus 120, that is, either the adjustment workpiece 700 or the regular workpiece 800.

The grinding apparatus 120 has a first apparatus base 122 and a second apparatus base 123 disposed in the rear (+Y direction) of the first apparatus base 122.

A first cassette stage 160 and a second cassette stage 162 for placing cassettes that house processing target workpieces are disposed on the front side (in −Y direction) of the first apparatus base 122.

The above-described first cassette 112 in which processing target workpieces that are yet to be processed are housed is placed on the first cassette stage 160. A second cassette 163 in which processing target workpieces that have been processed are housed is placed on the second cassette stage 162.

Openings (not illustrated) of the first cassette 112 and the second cassette 163 are facing towards the +Y direction. A second robot 155 is disposed on the side of these openings in the +Y direction. The second robot 155 as well as a loading mechanism 170 and an unloading mechanism 172 to be described later function as a transporting mechanism that transports a workpiece or a wafer between the cassette stage 160 or 162 and the chuck table 140.

The second robot 155 has a configuration similar to that of the first robot 115. Specifically, as illustrated in FIG. 3, the second robot 155 includes the robot hand 116 that has the holding surface 118 for holding a processing target workpiece thereon and the moving mechanism 117 that moves the robot hand 116.

The second robot 155 loads (carries) a processing target workpiece that has been processed, into the second cassette 163. In addition, the second robot 155 takes a processing target workpiece that is yet to be processed out from the first cassette 112, and places the processing target workpiece on a temporary placement table 154 such that one surface of the processing target workpiece is oriented upward. As described above, the one surface of the adjustment workpiece 700 is a flat surface, and the first residual peeling layer 900 is formed on the one surface of the regular workpiece 800.

The second robot 155 can also invert a processing target workpiece held thereon. That is, the second robot 155 also functions as an inverting mechanism that inverts the upper surface and lower surface of the processing target workpiece.

A camera 152 is disposed in the vicinity of the temporary placement table 154. The camera 152 captures an image of the one surface of the processing target workpiece placed on the temporary placement table 154. An image determining unit 153 to be described later is connected to the camera 152.

Further, the loading mechanism 170 is disposed at a position adjacent to the temporary placement table 154. The loading mechanism 170 holds under suction, by a suction pad 171, the processing target workpiece temporarily placed on the temporary placement table 154, and places the processing target workpiece on a holding surface 142 of the chuck table 140 such that the one surface of the processing target workpiece is oriented upward.

The holding surface 142 of the chuck table 140 is made to communicate with a suction source (not illustrated), and can hold the processing target workpiece thereon under suction. The chuck table 140 is rotatable about a central axis passing through the center of the holding surface 142 and extending in a Z-axis direction in a state in which the holding surface 142 holds the processing target workpiece thereon under suction.

In the present embodiment, on an upper surface of a turn table 145 disposed on the second apparatus base 123, three chuck tables 140 are arranged at equal intervals on a circle whose center corresponds to the center of the turn table 145. A rotary shaft, which is not illustrated, for rotating the turn table 145 is disposed at the center of the turn table 145. The rotary shaft enables the turn table 145 to rotate about an axis extending in the Z-axis direction. The three chuck tables 140 revolve when the turn table 145 rotates. Thus, the chuck tables 140 can sequentially be moved to a position in the vicinity of the temporary placement table 154, a position below the peeling layer grinding mechanism 132, and a position below the finish grinding mechanism 133.

A first column 124 is erected in the rear (+Y direction side) of the second apparatus base 123. A front surface of the first column 124 is provided with the peeling layer grinding mechanism 132 and a peeling layer grinding feed mechanism 130 that grinding-feeds the peeling layer grinding mechanism 132.

The peeling layer grinding feed mechanism 130 includes a pair of guide rails 201 parallel with the Z-axis direction, a raising and lowering table 203 that slides on the guide rails 201, a ball screw 200 parallel with the guide rails 201, a motor 202 that rotationally drives the ball screw 200, and a holder 204 attached to the raising and lowering table 203. The holder 204 holds the peeling layer grinding mechanism 132.

The raising and lowering table 203 is slidably installed on the guide rails 201. A nut portion not illustrated is fixed to the raising and lowering table 203. The ball screw 200 is screwed into the nut portion. The motor 202 is connected to one end portion of the ball screw 200.

In the peeling layer grinding feed mechanism 130, the motor 202 rotates the ball screw 200, and thus, the raising and lowering table 203 moves in the Z-axis direction along the guide rails 201. Consequently, the holder 204 attached to the raising and lowering table 203 and the peeling layer grinding mechanism 132 held by the holder 204 move in the Z-axis direction together with the raising and lowering table 203. The peeling layer grinding feed mechanism 130 thus grinding-feeds the peeling layer grinding mechanism 132 along the Z-axis direction.

The peeling layer grinding mechanism 132 grinds the first residual peeling layer 900 of a regular workpiece 800 held on the holding surface 142 of the chuck table 140 by peeling layer grindstones 306. The peeling layer grinding mechanism 132 includes a spindle housing 301 fixed to the holder 204, a spindle 300 rotatably held by the spindle housing 301, a motor 302 that rotationally drives the spindle 300, a wheel mount 303 attached to a lower end of the spindle 300, and a grinding wheel 304 detachably connected to a lower surface of the wheel mount 303.

The spindle housing 301 is held by the holder 204 to extend in the Z-axis direction. The spindle 300 extends in the Z-axis direction to be orthogonal to the holding surface 142 of the chuck table 140, and is rotatably supported by the spindle housing 301.

The motor 302 is connected to the upper end side of the spindle 300. This motor 302 rotates the spindle 300 about a rotational axis extending in the Z-axis direction.

The wheel mount 303 is formed in a disk shape. The wheel mount 303 is fixed to a lower end (distal end) of the spindle 300 and rotates according to the rotation of the spindle 300. The wheel mount 303 supports the grinding wheel 304.

The grinding wheel 304 has substantially the same outside diameter as the outside diameter of the wheel mount 303. The grinding wheel 304 includes an annular wheel base 305 formed of a metallic material, for example. A plurality of peeling layer grindstones 306 in substantially a rectangular parallelepipedic shape are annularly arranged and fixed over the entire circumference of a lower surface of the wheel base 305. The peeling layer grindstones 306 are rotated by the rotation of the spindle 300 to grind the processing target workpiece held on the chuck table 140. The peeling layer grindstones 306 are, for example, grindstones including relatively large abrasive grains.

A first height gage 143 is disposed at a position adjacent to the chuck table 140 disposed below the peeling layer grinding mechanism 132. The first height gage 143 and a second height gage 144 to be described later are a thickness measuring instrument that measures the thickness of the processing target workpiece held on the holding surface 142. The first height gage 143 measures the thickness of the processing target workpiece in a contact manner or a noncontact manner. A thickness determining unit 141 to be described later is connected to the first height gage 143.

In addition, a second column 125 is erected in the rear of the second apparatus base 123 at a position adjacent to the first column 124 along the X-axis direction. A front surface of the second column 125 is provided with the finish grinding mechanism 133 that finish-grinds the processing target workpiece and a finish grinding feed mechanism 131 that grinding-feeds the finish grinding mechanism 133. The finish grinding mechanism 133 is an example of a processing mechanism that processes the workpiece held on the holding surface 142 under suction.

The finish grinding feed mechanism 131 has a configuration similar to that of the peeling layer grinding feed mechanism 130. The finish grinding feed mechanism 131 can grinding-feed the finish grinding mechanism 133 along the Z-axis direction. The finish grinding mechanism 133 grinds the processing target workpiece held on the holding surface 142 of the chuck table 140, by finish grindstones 307. The finish grinding mechanism 133 has a configuration similar to that of the peeling layer grinding mechanism 132 except that the finish grinding mechanism 133 has the finish grindstones 307 in place of the peeling layer grindstones 306. The finish grindstones 307 are, for example, grindstones including relatively small abrasive grains.

A second height gage 144 is disposed at a position adjacent to the chuck table 140 disposed below the finish grinding mechanism 133. The second height gage 144 measures the thickness of the processing target workpiece in a contact manner or a noncontact manner.

The processing target workpiece that has been finish-ground is a wafer having a predetermined thickness and is unloaded by the unloading mechanism 172. The unloading mechanism 172 holds the wafer held on the chuck table 140, by a suction pad 173 under suction, and transports the wafer to a spinner cleaning mechanism 156.

The spinner cleaning mechanism 156 is a spinner cleaning unit that cleans the wafer. The spinner cleaning mechanism 156 includes a spinner table 157 that holds the wafer thereon and a nozzle 158 that jets cleaning water and drying air to the spinner table 157.

The second robot 155 loads the wafer cleaned by the spinner cleaning mechanism 156 into the second cassette 163 on the second cassette stage 162.

In addition, the grinding apparatus 120 has a casing 135 that covers the first apparatus base 122 and the second apparatus base 123. A touch panel 136 is installed on a side surface of the casing 135.

The touch panel 136 displays various kinds of information related to grinding by the grinding apparatus 120. The touch panel 136 is also used to input various kinds of information such as device data. Thus, the touch panel 136 functions as a display member for displaying information and also functions as an input member for inputting information.

In addition, the grinding apparatus 120 has therein a second controller 180 for controlling the grinding apparatus 120. The second controller 180 includes a CPU that performs arithmetic processing according to a control program, a storage medium such as a memory, and the like. The second controller 180 controls each of the above-described members of the grinding apparatus 120 to perform the step of grinding processing target workpieces.

The grinding step of the wafer manufacturing method according to the present embodiment which is performed by the grinding apparatus 120 having such a configuration as described above will be described in the following.

[3. Grinding Step]

In the grinding step, wafers having a predetermined thickness are manufactured by grinding opposite surfaces of each of the adjustment workpiece 700 from which the first residual peeling layer 900 has been removed and the regular workpiece 800 having the first residual peeling layer 900.

(3-1. Holding Step)

First, the second controller 180 controls the second robot 155 to take a processing target workpiece out from the first cassette 112 and place the processing target workpiece on the temporary placement table 154 such that one surface of the processing target workpiece is oriented upward. Further, the second controller 180 controls the loading mechanism 170 to place the processing target workpiece, which is temporarily placed on the temporary placement table 154, on the holding surface 142 of the chuck table 140 such that the one surface of the processing target workpiece is oriented upward. Hence, the holding surface 142 holds the other surface of the processing target workpiece thereon (holding step).

Then, the second controller 180 rotates the turn table 145 to position the chuck table 140 holding the processing target workpiece thereon below the peeling layer grinding mechanism 132.

(3-2. Peeling Layer Presence or Absence Determining Step)

In this step, the thickness determining unit 141 determines whether the first residual peeling layer 900 is present or absent on the one surface of the processing target workpiece.

Specifically, the thickness determining unit 141 measures the thickness of the processing target workpiece held on the holding surface 142 of the chuck table 140, by using the first height gage 143 (fourth thickness measuring step).

Then, when the thickness of the processing target workpiece is equal to or more than a thickness set in advance, the thickness determining unit 141 determines that the first residual peeling layer 900 is present on the processing target workpiece. When the thickness of the processing target workpiece does not reach the thickness set in advance (when the thickness of the processing target workpiece is smaller than the thickness set in advance), on the other hand, the thickness determining unit 141 determines that the first residual peeling layer 900 is absent on the processing target workpiece (thickness determining step).

Thus, in this peeling layer presence or absence determining step, the first height gage 143 and the thickness determining unit 141 function as a peeling layer presence or absence detecting unit that detects whether the first residual peeling layer 900 is present or absent on the one surface of the processing target workpiece.

When the thickness determining unit 141 determines that the first residual peeling layer 900 is present, the second controller 180 determines that the processing target workpiece is a regular workpiece 800, and performs a peeling layer grinding step and a finish grinding step described in the following.

(3-3. Peeling Layer Grinding Step)

In the peeling layer grinding step, the second controller 180 causes the peeling layer grindstones 306 to grind and remove the first residual peeling layer 900 of the regular workpiece 800.

Specifically, the second controller 180 controls the peeling layer grinding feed mechanism 130 to lower the peeling layer grinding mechanism 132 along the Z-axis direction in a state in which the chuck table 140 holding the regular workpiece 800 thereon and the peeling layer grindstones 306 of the peeling layer grinding mechanism 132 are rotated. Consequently, the peeling layer grindstones 306 come into contact with one surface of the regular workpiece 800, and the first residual peeling layer 900 formed on this surface is removed by the peeling layer grindstones 306. After such a peeling layer grinding step, the finish grinding step is performed.

Incidentally, in the peeling layer grinding step, the regular workpiece 800 is ground into such a thickness that includes an extra thickness corresponding to an amount of grinding by the finish grindstones 307, that is, such a thickness as to secure portions to be ground by the finish grindstones 307.

(3-4. Finish Grinding Step)

In the finish grinding step, the second controller 180 causes the finish grindstones 307 to grind opposite surfaces of the regular workpiece 800 such that the regular workpiece 800 has a predetermined thickness.

Specifically, the second controller 180 rotates the turn table 145 to position, below the finish grinding mechanism 133, the chuck table 140 holding the regular workpiece 800 which has undergone the peeling layer grinding step. Then, the second controller 180 controls the finish grinding feed mechanism 131 to lower the finish grinding mechanism 133 along the Z-axis direction in a state in which the chuck table 140 and the finish grindstones 307 of the finish grinding mechanism 133 are rotated. Consequently, the finish grindstones 307 come into contact with the one surface of the regular workpiece 800 and finish-grind this surface by a predetermined grinding amount.

Next, the second controller 180 causes the regular workpiece 800 on the chuck table 140 to be inverted (inverting step). Specifically, the second controller 180 rotates the turn table 145 to position, in the vicinity of the temporary placement table 154, the chuck table 140 holding the regular workpiece 800 whose one surface is finish-ground. Then, the second controller 180 controls the unloading mechanism 172 to transfer the regular workpiece 800 held on the chuck table 140 to the second robot 155. Then, the second controller 180 controls the second robot 155 to invert the regular workpiece 800 and place the regular workpiece 800 on the temporary placement table 154 such that the other surface of the regular workpiece 800 is oriented upward. Further, the second controller 180 makes the loading mechanism 170 place the regular workpiece 800, which is temporarily placed on the temporary placement table 154, on the holding surface 142 of the chuck table 140 such that the other surface of the regular workpiece 800 is oriented upward. Hence, the holding surface 142 holds the regular workpiece 800 thereon.

Thereafter, the second controller 180 rotates the turn table 145 to position the chuck table 140 holding the regular workpiece 800 thereon below the finish grinding mechanism 133, and controls the finish grinding mechanism 133 to finish-grind the other surface of the regular workpiece 800 by a predetermined grinding amount such that the regular workpiece 800 has a predetermined thickness. Consequently, a wafer having the predetermined thickness is manufactured from the regular workpiece 800.

Incidentally, in the finish grinding step, grinding traces formed on the one surface of the regular workpiece 800 by the peeling layer grindstones 306 and grinding traces formed on the other surface of the regular workpiece 800 by the peeling layer grindstones 84 (see FIG. 2) of the laser processing apparatus 1 are ground and removed by the finish grindstones 307. In the finish grinding step, for example, opposite surfaces of the regular workpiece 800 are ground down by the same amount (for example, 5 or 10 μm).

When the thickness determining unit 141 determines that the first residual peeling layer 900 is absent on the processing target workpiece, on the other hand, the second controller 180 determines that the processing target workpiece is an adjustment workpiece 700. Then, without causing the peeling layer grindstones 306 to grind the adjustment workpiece 700, the second controller 180 causes the finish grindstones 307 to grind opposite surfaces of the adjustment workpiece 700 such that the adjustment workpiece 700 has the predetermined thickness.

That is, the second controller 180 does not perform the above-described peeling layer grinding step, but performs only the above-described finish grinding step to grind opposite surfaces of the adjustment workpiece 700 by the finish grindstones 307 such that the adjustment workpiece 700 has the predetermined thickness. In the finish grinding step, grinding traces formed on the adjustment workpiece 700 by the peeling layer grindstones 84 (see FIG. 2) of the laser processing apparatus 1 are ground and removed by the finish grindstones 307. Consequently, a wafer having the predetermined thickness is manufactured from the adjustment workpiece 700.

The wafers which are manufactured from the adjustment workpiece 700 and the regular workpiece 800 and which have the predetermined thickness are transported to the spinner cleaning mechanism 156 by the unloading mechanism 172 and cleaned by the spinner cleaning mechanism 156, and are then loaded into the second cassette 163 on the second cassette stage 162 by the second robot 155.

As described above, in the present embodiment, in both a case where the processing target workpiece is a regular workpiece 800 having the first residual peeling layer 900 on one surface thereof and a case where the processing target workpiece is an adjustment workpiece 700 not having the first residual peeling layer 900, a wafer having the predetermined thickness is manufactured from the processing target workpiece by grinding opposite surfaces of the processing target workpiece. That is, in the present embodiment, because opposite surfaces of the processing target workpiece are ground, wafers can be manufactured from two kinds of processing target workpieces irrespective of whether or not the first residual peeling layer 900 is present on one surface. Hence, even when two kinds of processing target workpieces are housed in the first cassette 112 in a mixed manner, wafers having the predetermined thickness can be manufactured easily from these processing target workpieces. It is thus possible to shorten an overall processing time as compared with a case where the adjustment workpiece 700 and the regular workpiece 800 are ground separately.

In addition, in the present embodiment, the thickness determining unit 141 detects the presence or absence of the first residual peeling layer 900, and whether or not to perform the peeling layer grinding step is determined on the basis of a result of the detection. Hence, the adjustment workpiece 700 and the regular workpiece 800 can be subjected to appropriate grinding processing according to the presence or absence of the first residual peeling layer 900.

Incidentally, the grinding step may include the following first determining step. In the first determining step, the second controller 180 determines that a wafer cannot be manufactured, when the thickness of the processing target workpiece measured in the fourth thickness measuring step in the peeling layer presence or absence determining step is smaller than at least a value obtained by adding together the grinding amount by which grinding is performed by the finish grindstones 307, the grinding amount being set in advance, and the predetermined thickness of a wafer which is set in advance. Then, the second controller 180 stops the grinding step without performing the peeling layer grinding step and the finish grinding step described above, and notifies the operator that a wafer cannot be manufactured, by use of the touch panel 136.

In addition, in the present embodiment, the peeling layer presence or absence determining step may be performed by using the camera 152 and the image determining unit 153. In this case, in the peeling layer presence or absence determining step, an imaging step and an image determining step are performed as follows.

In the imaging step, the second controller 180 controls the camera 152 to capture an image of the one surface of the processing target workpiece which is placed on the temporary placement table 154 such that the one surface is oriented upward. The second controller 180 thus obtains the captured image (imaging step).

In the case where the first residual peeling layer 900 is present on the one surface of the processing target workpiece, a captured image of the first residual peeling layer 900 is obtained as the captured image of the one surface. As illustrated in FIG. 12, in the captured image of the first residual peeling layer 900, gray parts and black parts mixedly appear in such a manner as to be adjacent to one another. In the case where the first residual peeling layer 900 is absent on the one surface of the processing target workpiece, on the other hand, a captured image (not illustrated) of a flat ground surface ground by the peeling layer grindstones 84 (see FIG. 2) of the laser processing apparatus 1 is obtained as the captured image of the one surface. Only a substantially uniform gray part is displayed in the captured image of the ground surface.

Next, the image determining unit 153 determines whether or not a difference in brightness between pixels adjacent to each other in the image captured by the camera 152 is equal to or more than a difference set in advance.

As described above, in the captured image of the first residual peeling layer 900, gray parts and black parts mixedly appear in such a manner as to be adjacent to one another. Thus, the difference in brightness between the pixels adjacent to each other in the captured image is relatively large. Hence, the image determining unit 153 determines that the first residual peeling layer 900 is present on the processing target workpiece, when the difference in brightness between the pixels is equal to or more than the difference set in advance.

On the other hand, in the captured image of the ground surface where the first residual peeling layer 900 is absent, only the substantially uniform gray part is displayed. Thus, the difference in brightness between the pixels adjacent to each other in the captured image is relatively small. Hence, the image determining unit 153 determines that the first residual peeling layer 900 is absent on the processing target workpiece, when the difference in brightness between the pixels is smaller than the difference set in advance (image determining step).

When the image determining unit 153 determines that the first residual peeling layer 900 is present on the processing target workpiece, the second controller 180 determines that the processing target workpiece is a regular workpiece 800, and performs the peeling layer grinding step and the finish grinding step described above.

When the image determining unit 153 determines that the first residual peeling layer 900 is absent on the processing target workpiece, on the other hand, the second controller 180 determines that the processing target workpiece is an adjustment workpiece 700, and performs only the finish grinding step without performing the peeling layer grinding step described above.

Thus, in the peeling layer presence or absence determining step, the camera 152 and the image determining unit 153 function as a peeling layer presence or absence detecting unit that detects whether the first residual peeling layer 900 is present or absent on the one surface of the processing target workpiece.

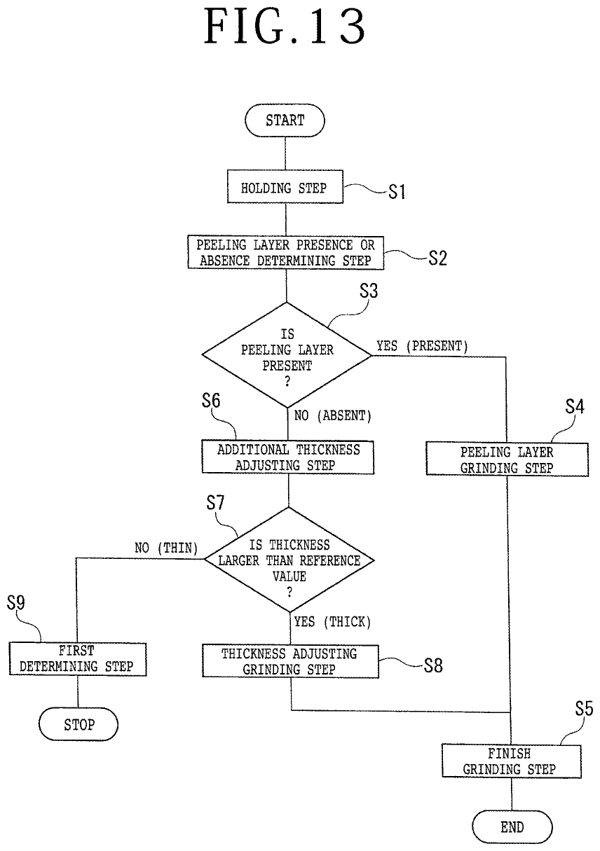

In addition, the second controller 180 may perform the grinding step as illustrated in a flowchart of FIG. 13. First, the second controller 180 performs the holding step described above to position the chuck table 140 holding the processing target workpiece thereon below the peeling layer grinding mechanism 132 (S1).

Next, the second controller 180 performs the peeling layer presence or absence determining step on the basis of the thickness of the processing target workpiece by using the first height gage 143 and the thickness determining unit 141 (S2).

Incidentally, the second controller 180 may perform the peeling layer presence or absence determining step on the basis of a captured image of the processing target workpiece by using the camera 152 and the image determining unit 153.

Then, when the second controller 180 determines in the peeling layer presence or absence determining step that the first residual peeling layer 900 is present on the processing target workpiece (S3; YES), the second controller 180 determines that the processing target workpiece is a regular workpiece 800. Then, the second controller 180 performs the above-described peeling layer grinding step (S4) to grind and remove the first residual peeling layer 900 from the regular workpiece 800 by the peeling layer grindstones 306.

Further, the second controller 180 performs the above-described finish grinding step (S5) to grind opposite surfaces of the regular workpiece 800 by the finish grindstones 307 such that the regular workpiece 800 has the predetermined thickness. Thus, a wafer having the predetermined thickness is manufactured. The second controller 180 then ends the grinding step.

When the second controller 180 determines in the peeling layer presence or absence determining step that the first residual peeling layer 900 is absent on the processing target workpiece (S3; NO), on the other hand, the second controller 180 determines that the processing target workpiece is an adjustment workpiece 700. Then, the second controller 180 performs an additional thickness measuring step to measure the thickness of the adjustment workpiece 700 held on the holding surface 142 of the chuck table 140, by using the first height gage 143 (see FIG. 11) (S6).

Then, the second controller 180 determines whether or not the thickness of the adjustment workpiece 700 measured in the additional thickness measuring step is larger than a reference value (S7). This reference value is a value obtained by adding the grinding amount by which grinding is performed by the finish grindstones 307, the grinding amount being set in advance, and the predetermined thickness of a wafer (thickness of a wafer that has undergone the finish grinding step)which is set in advance.

When the thickness of the adjustment workpiece 700 measured in the additional thickness measuring step is larger than the reference value (S7; YES), the second controller 180 performs a thickness adjusting grinding step (S8).

As described above, grinding traces are formed on the adjustment workpiece 700 by the peeling layer grindstones 84 (see FIG. 2) of the laser processing apparatus 1. In the thickness adjusting grinding step, the second controller 180 causes the peeling layer grindstones 306 of the grinding apparatus 120 to grind, while forming grinding traces that intersect the grinding traces formed on the adjustment workpiece 700 by the peeling layer grindstones 84, the adjustment workpiece 700 to a thickness of a value obtained by adding together the grinding amount by which grinding is performed by the finish grindstones 307 and the predetermined thickness of a wafer which is set in advance (that is, the value is the reference value).

Specifically, when the one surface of the adjustment workpiece 700 held on the rotating chuck table 140 is ground by the rotating peeling layer grindstones 306, the second controller 180 appropriately adjusts at least any of the inclination of the chuck table 140, the rotational direction of the chuck table 140, and the rotational direction of the peeling layer grindstones 306. Consequently, the second controller 180 can cause the peeling layer grindstones 306 to grind the one surface of the adjustment workpiece 700 in such a manner as to form grinding traces intersecting the grinding traces formed on the one surface of the adjustment workpiece 700 by the peeling layer grindstones 84.

The second controller 180 performs such grinding by the peeling layer grindstones 306 until the adjustment workpiece 700 reaches the thickness of the reference value.

Incidentally, after the one surface of the adjustment workpiece 700 is ground by a predetermined amount by the peeling layer grindstones 306, the second controller 180 may perform the above-described inverting step to hold the adjustment workpiece 700 on the chuck table 140 such that the other surface of the adjustment workpiece 700 is oriented upward. Then, the second controller 180 may cause the peeling layer grindstones 306 to grind the other surface of the adjustment workpiece 700 to form grinding traces intersecting the grinding traces formed on this surface by the peeling layer grindstones 84. Then, the second controller 180 may use the thickness of the adjustment workpiece 700 as the thickness of the reference value.

Thereafter, the second controller 180 performs the above-described finish grinding step (S5) to grind opposite surfaces of the adjustment workpiece 700 by the finish grindstones 307 such that the adjustment workpiece 700 has the predetermined thickness. Thus, a wafer having the predetermined thickness is manufactured. The second controller 180 then ends the grinding step.

When the thickness of the adjustment workpiece 700 measured in the additional thickness measuring step is equal to or less than the reference value (S7; NO), on the other hand, the second controller 180 performs the above-described first determining step to determine that a wafer cannot be manufactured. Then, the second controller 180 stops the grinding step without performing the peeling layer grinding step and the finish grinding step described above, and notifies the operator that a wafer cannot be manufactured, by using the touch panel 136.

In the grinding step, the adjustment workpiece 700 is ground by the peeling layer grindstones 306 and is then ground by the finish grindstones 307. Hence, it is possible to suppress wear of the finish grindstones 307 as compared with a configuration in which the adjustment workpiece 700 is ground by only the finish grindstones 307.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method for manufacturing a wafer by forming a peeling layer in an ingot, peeling off a plate-shaped workpiece from the ingot with the peeling layer as a starting point, and grinding the workpiece with use of grinding stones, the peeling layer being formed by applying a laser beam having a wavelength transmissible through the ingot to the ingot from a side of one surface of the ingot while a focused spot of the laser beam is positioned inside the ingot at a predetermined depth and then moving the focused spot of the laser beam in parallel with the one surface of the ingot, the method comprising:
a power adjusting step of forming an adjustment peeling layer in the ingot, peeling off an adjustment workpiece from the ingot with the adjustment peeling layer as a starting point, removing a first residual peeling layer that is a peeling layer remaining on the adjustment workpiece, and adjusting power of the laser beam to be applied to the ingot;
a workpiece obtaining step of obtaining a workpiece having a first residual peeling layer on one surface of the workpiece by forming a peeling layer in the ingot through application of the laser beam adjusted in power to the ingot and peeling off the workpiece from the ingot with the peeling layer as a starting point; and
a grinding step of grinding opposite surfaces of the adjustment workpiece from which the first residual peeling layer has been removed and opposite surfaces of the workpiece having the first residual peeling layer, to manufacture wafers having a predetermined thickness.

2. The method for manufacturing a wafer according to claim 1, wherein
the power adjusting step includes
a first thickness measuring step of measuring a first thickness that is a thickness of the ingot in which the adjustment peeling layer is yet to be formed,
a first peeling layer forming step of forming the adjustment peeling layer in the ingot,
a first peeling step of peeling off the adjustment workpiece from the ingot with the adjustment peeling layer as a starting point,
a first ingot grinding step of grinding and removing, by peeling layer grindstones, a second residual peeling layer that is a peeling layer remaining on the ingot,
a second thickness measuring step of measuring a second thickness that is a thickness of the ingot from which the second residual peeling layer has been removed through the grinding,
a workpiece grinding step of grinding and removing, by the peeling layer grindstones, the first residual peeling layer of the adjustment workpiece peeled off from the ingot,
a third thickness measuring step of measuring a third thickness that is a thickness of the adjustment workpiece from which the first residual peeling layer has been removed through the grinding,
an adjustment peeling layer thickness measuring step of measuring a thickness of the adjustment peeling layer by subtracting the second thickness and the third thickness from the first thickness, and
an adjusting step of adjusting the power of the laser beam such that the thickness of the adjustment peeling layer measured in the adjustment peeling layer thickness measuring step corresponds to a thickness set in advance.

3. The method for manufacturing a wafer according to claim 1, wherein
the workpiece obtaining step includes
a second peeling layer forming step of forming the peeling layer in the ingot through the application of the laser beam adjusted in power to the ingot,
a second peeling step of peeling off the workpiece from the ingot with the peeling layer as a starting point to obtain the workpiece having the first residual peeling layer and the ingot having a second residual peeling layer remaining after the workpiece is peeled off,
a second ingot grinding step of grinding and removing the second residual peeling layer of the ingot after the second peeling step, and
a repeating step of repeating the second peeling layer forming step, the second peeling step, and the second ingot grinding step to obtain workpieces each having the first residual peeling layer.

4. The method for manufacturing a wafer according to claim 3, wherein
the workpiece obtaining step includes
housing, in a cassette in a mixed manner, the workpieces that are obtained in the repeating step and that each have the first residual peeling layer and the adjustment workpiece that is obtained in the power adjusting step and from which the first residual peeling layer has been removed.

5. The method for manufacturing a wafer according to claim 1, wherein
the grinding step includes
a holding step of holding, on a holding surface of a chuck table, another surface of the workpiece having the first residual peeling layer on the one surface thereof,
a peeling layer grinding step of grinding and removing, by peeling layer grindstones, the first residual peeling layer of the workpiece held on the holding surface, and
a finish grinding step of grinding and removing, by finish grindstones, grinding traces formed on the opposite surfaces of the workpiece ground by the peeling layer grindstones.

6. The method for manufacturing a wafer according to claim 1, wherein
the grinding step includes a peeling layer presence or absence determining step of determining whether the first residual peeling layer is present or absent on the one surface of the workpiece,
when it is determined that the first residual peeling layer is present, the first residual peeling layer of the workpiece is ground and removed by peeling layer grindstones, and the opposite surfaces of the workpiece are then ground by finish grindstones, and
when it is determined that the first residual peeling layer is absent, the opposite surfaces of the workpiece are ground by the finish grindstones without performing the grinding by the peeling layer grindstones.

7. The method for manufacturing a wafer according to claim 6, wherein
the peeling layer presence or absence determining step includes
a fourth thickness measuring step of measuring a thickness of the workpiece held on a holding surface of a chuck table, and
a thickness determining step of determining that the first residual peeling layer is present on the workpiece, when the thickness of the workpiece measured in the fourth thickness measuring step is equal to or more than a thickness set in advance, and determining that the first residual peeling layer is absent on the workpiece, when the thickness of the workpiece is smaller than the thickness set in advance.

8. The method for manufacturing a wafer according to claim 6, wherein
the peeling layer presence or absence determining step includes
an imaging step of capturing an image of the one surface of the workpiece, and
an image determining step of determining that the first residual peeling layer is present on the workpiece, when a difference in brightness between pixels adjacent to each other in the captured image is equal to or more than a difference set in advance, and determining that the first residual peeling layer is absent on the workpiece, when the difference in brightness between the pixels is smaller than the difference set in advance.

9. The method for manufacturing a wafer according to claim 7, wherein
the grinding step includes
a first determining step of determining that the wafer is not able to be manufactured, when the thickness of the workpiece measured in the fourth thickness measuring step is smaller than at least a value obtained by adding together a grinding amount by which grinding is performed by the finish grindstones, the grinding amount being set in advance, and the predetermined thickness of the wafer set in advance.

10. The method for manufacturing a wafer according to claim 1, wherein
the grinding step includes a peeling layer presence or absence determining step of determining whether the first residual peeling layer is present or absent on the one surface of the workpiece,
when it is determined that the first residual peeling layer is present, the first residual peeling layer of the workpiece is ground and removed by peeling layer grindstones, and the opposite surfaces of the workpiece are then ground by finish grindstones, and
when it is determined that the first residual peeling layer is absent,
an additional thickness measuring step of measuring a thickness of the workpiece,
a thickness adjusting grinding step of, when the thickness measured in the additional thickness measuring step is larger than a reference value that is a value obtained by adding together a grinding amount by which grinding is performed by the finish grindstones and the predetermined thickness of the wafer set in advance, grinding the workpiece by the peeling layer grindstones to a thickness of the reference value while forming grinding traces intersecting grinding traces formed on the workpiece, and
a finish grinding step of grinding the opposite surfaces of the workpiece by the finish grindstones after the thickness adjusting grinding step are performed.

11. A grinding apparatus comprising:
a cassette stage where a cassette in which workpieces are housed is placed;
a chuck table having a holding surface for holding a workpiece thereon;
a peeling layer grinding mechanism configured to grind, by peeling layer grindstones, a first residual peeling layer of the workpiece held on the holding surface;
a finish grinding mechanism configured to grind, by finish grindstones, the workpiece held on the holding surface;
a transporting mechanism configured to transport the workpiece between the cassette stage and the chuck table;
an inverting mechanism configured to invert an upper surface and a lower surface of the workpiece;
a thickness measuring instrument configured to measure a thickness of the workpiece held on the holding surface;
a peeling layer presence or absence detecting unit configured to detect whether the first residual peeling layer is present or absent on one surface of the workpiece; and
a controller;
the controller being configured to
perform control such that, when the peeling layer presence or absence detecting unit determines that the first residual peeling layer is present, the first residual peeling layer of the workpiece is ground and removed by the peeling layer grindstones and opposite surfaces of the workpiece are then ground by the finish grindstones, and
perform control such that, when the peeling layer presence or absence detecting unit determines that the first residual peeling layer is absent, the opposite surfaces of the workpiece are ground by the finish grindstones without performing the grinding by the peeling layer grindstones.

12. The grinding apparatus according to claim 11, wherein
the peeling layer presence or absence detecting unit includes
a thickness determining unit configured to measure, by the thickness measuring instrument, the thickness of the workpiece held on the holding surface, determine that the first residual peeling layer is present on the workpiece, when the thickness of the workpiece is equal to or more than a thickness set in advance, and determine that the first residual peeling layer is absent on the workpiece, when the thickness of the workpiece does not reach the thickness set in advance.

13. The grinding apparatus according to claim 11, wherein
the peeling layer presence or absence detecting unit includes
a camera configured to capture an image of the one surface of the workpiece, and
an image determining unit configured to determine that the first residual peeling layer is present on the workpiece, when a difference in brightness between pixels adjacent to each other in the image captured by the camera is equal to or more than a difference set in advance, and determine that the first residual peeling layer is absent on the workpiece, when the difference in brightness between the pixels is smaller than the difference set in advance.
